(19) United States
(12) Patent Application Publication
(10) Pub. No.: US 2015/0357259 A1
(43) Pub. Date: Dec. 10, 2015

(54) SEMICONDUCTOR RADIATOR

(71) Applicant: Jingyi Gu, Shenzhen City (CN)

(72) Inventor: Jingyi Gu, Shenzhen City (CN)

(21) Appl. No.: 14/384,903

(22) PCT Filed: Apr. 28, 2014
(86) PCT No.: PCT/CN2014/076369

§ 371 Date: Sep. 12, 2014

(30) Foreign Application Priority Data
Feb. 15, 2014 (CN) 201410051343.0

(51) Int. Cl. H01L 23/367; H01L 23/40

(52) U.S. Cl. CPC H01L 23/3675; H01L 23/4093; H01L 23/4006; H01L 2023/4081; H01L 2023/4087

(57) ABSTRACT

The present invention discloses a semiconductor radiator, a hollow thermally insulating stand and a lower heat conductive connection base are arranged on an upper end and a lower end of the through hole arranged on an electrically and thermally insulating rigid substrate respectively, a stage which extends through the through hole and cooperates with a cavity of the hollow thermally insulating stand is arranged on the lower heat conductive connection base, a top surface of the stage is attached to a bottom surface of a semiconductor cooling plate arranged on the top of the hollow thermally insulating stand, an upper heat conductive connection base is attached to a top surface of the semiconductor cooling plate. The present invention has a simple structure, a good anti-dust capability, a noise-free feature, a stable and reliable heat dissipation performance, and easy installation.

This application claims priority to a Chinese patent application No. 201410051343.0 filed on Feb. 15, 2014 in the name of Jingyi GU and entitled “Semiconductor Radiator”, the disclosure of which is incorporated herein by reference in its entirety.

### TECHNICAL FIELD

The present disclosure relates to the field of heat dissipation technologies, and in particularly to a semiconductor radiator.

### BACKGROUND

Nowadays, popular semiconductor radiators have disadvantages of poor heat insulation between a hot end and a cold end, a poor anti-dust capability and difficult installation in use due to its structure and design principles. Because heat dissipation means such as fans are used in many electronic devices, a lot of dusts enter into the electronic devices along with wind for heat dissipation. If the dusts within the electronic device are not cleared up in time, problems such as a wind duct blockage, a rising temperature and a shorted circuit may be likely caused in the electronic device, thus a high failure rate of the electronic devices, as well as a variety of faults or accidents such as a burned out electronic device and a sudden halt of the electronic device, can be caused. Actually, accessories such as the fan per se are considered as one of fault sources. In addition, the electronic device provided with the fan makes much noise while dissipating the heat, which can cause negative effects on the noise-free environment required for work and videos.

### SUMMARY

It is an object of the present disclosure to provide a semiconductor radiator, which has advantageous of a simple structure, a good anti-dust capability, a noise-free feature, a stable and reliable heat dissipation performance, and easy installation.

In order to achieve the above object, the present disclosure proposes the following technical solutions.

A semiconductor radiator includes an electrically and thermally insulating rigid substrate containing a through hole, where a hollow thermally insulating stand and a lower heat conductive connection base are arranged on an upper end and a lower end of the through hole, respectively, a stage which extends through the through hole and cooperates with a cavity of the hollow thermally insulating stand is arranged on the lower heat conductive connection base, a top surface of the stage is attached to a bottom surface of a semiconductor cooling plate arranged on the top of the hollow thermally insulating stand, an upper heat conductive connection base is attached to a top surface of the semiconductor cooling plate, and a number of heat dissipation means are fastened on each of an upper surface of the upper heat conductive connection base and a bottom surface of the lower heat conductive connection base.

A fixation component for fixing the semiconductor cooling plate is arranged at an upper opening of the hollow thermally insulating stand, and an outer side wall of the semiconductor cooling plate cooperates with an inner side wall at the upper opening of the hollow thermally insulating stand.

A clamping groove for snap-fitting with the fixation component is arranged on the outer side wall around the semiconductor cooling plate.

The fixation component includes a fixed member and a movable member, the fixed member is U-shaped and has a protrusion for snap-fitting with the clamping groove on an inner side wall of the fixed member, and the movable member snap-fits with a clamping groove on a side of the semiconductor cooling plate where a power line is arranged, and is fastened with the end face of the hollow thermally insulating stand.

The lower heat conductive connection base includes a base and a stage arranged on the top of the base, and a side wall of the stage is in an interference fit with the through hole and the inner side wall of the hollow thermally insulating stand.

A semiconductor radiator further includes a compression component for compressing the upper heat conductive connection base and the lower heat conductive connection base and a supporting component for preventing the semiconductor cooling plate from fracturing.

The compression component includes a U-shaped bolt and a pressing plate cooperating with the U-shaped bolt, and an elastic pressing flake is arranged on the bottom of the pressing plate.

The supporting component includes a number of pressure limiting screws for positioning and supporting arranged between the electrically and thermally insulating rigid substrate and the upper and lower heat conductive connection base and nuts cooperating with threads at both ends of the pressure limiting screws for positioning and supporting, where the nuts include a first nut for supporting and/or a second nut for locking.

The heat dissipation means is a heat sink provided with a ventilation hole and a ventilation groove at its bottom.

The present invention has the following advantages: the present invention includes an electrically and thermally insulating rigid substrate containing a through hole, where a hollow thermally insulating stand and a lower heat conductive connection base are arranged at an upper end and a lower end of the through hole, respectively, a stage which extends through the through hole and cooperates with a cavity of the hollow thermally insulating stand is arranged on the lower heat conductive connection base, a top surface of the stage is attached to a bottom surface of a semiconductor cooling plate arranged on the top of the hollow thermally insulating stand, an upper heat conductive connection base is attached to a top surface of the semiconductor cooling plate, and a number of heat dissipation means are fastened on an upper surface of the upper heat conductive connection base and a bottom surface of the lower heat conductive connection base. The state arranged on the hollow thermally insulating stand and the lower heat conductive connection base makes the heat dissipated from the heat source to be guided to the outside intensively through the semiconductor cooling plate ant its heat dissipation means arranged on the hollow thermally insulating stand, which functions as an effective anti-dust and intensive heat dissipation. Further, the electrically and thermally insulating rigid substrate makes the installation of the radiator convenient and makes the cold face and hot face of the semiconductor cooling plate separate effectively, and thus enhancing the heat dissipation efficiency. The present invention has a simple structure, a good anti-dust capability, a noise-free feature, a stable and reliable heat dissipation performance, and easy installation.

### BRIEF DESCRIPTION OF THE DRAWINGS

FIG. 1 is a schematic view showing a structure of a semiconductor radiator according to the present disclosure;

FIG. 2 is a schematic view showing a structure of a semiconductor cooling plate assembly in FIG. 1; and

FIG. 3 is a sectional view taken along a line A-A in FIG. 2.

### REFERENCE NUMERAL LIST

1. electrically and thermally insulating rigid substrate 2. hollow thermally insulating stand

3. lower heat conductive connection base 4. semiconductor cooling plate assembly

5. semiconductor cooling plate 6. upper heat conductive connection base

7. heat dissipation means 8. fixed member 9. movable member

10. U-shaped bolt 11. pressing plate 12. elastic pressing flake

13. pressure limiting screw for positioning and supporting

### DETAILED DESCRIPTION OF THE EMBODIMENTS

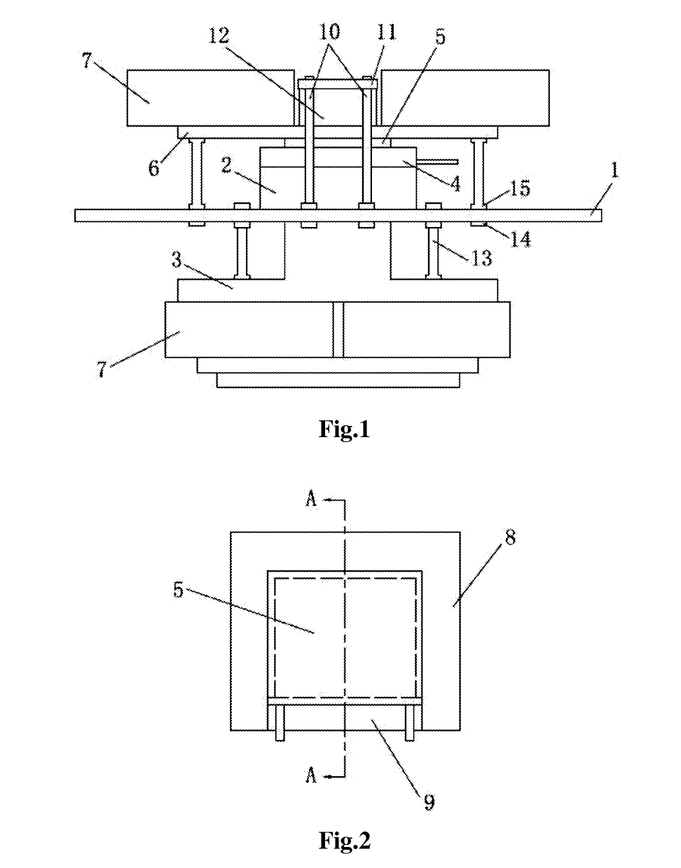

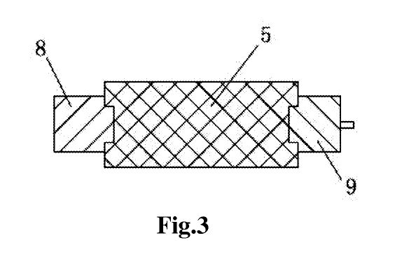

The technical solution of the present invention will be further described with reference to FIGS. 1-3 and embodiments of the present invention.

A semiconductor radiator includes an electrically and thermally insulating rigid substrate 1 containing a through hole, and a hollow thermally insulating stand 2 and a lower heat conductive connection base 3 are arranged at an upper end and a lower end of the through hole, respectively. A stage which extends through the through hole and cooperates with a cavity of the hollow thermally insulating stand 2 is arranged on the lower heat conductive connection base 3, a top surface of the stage is attached to a bottom surface of a semiconductor cooling plate 5 arranged on the top of the hollow thermally insulating stand 2, an upper heat conductive connection base 6 is attached to a top surface of the semiconductor cooling plate 5, and a number of heat dissipation means 7 are fastened on each of an upper surface of the upper heat conductive connection base 6 and a bottom surface of the lower heat conductive connection base 3. The hollow thermally insulating stand and the stage on the lower heat conductive connection base are arranged such that the stage extending through the through hole abuts against to the inner side wall of the hollow thermally insulating stand, while a gap between the stage and the through hole is sealed by a heat conductive glue, thus dusts are prevented effectively from entering to the through hole. At the same time, the hollow thermally insulating stand makes the heat from a heat source at the bottom of the stage be dissipated to the outside intensively through the semiconductor cooling plate and its corresponding heat dissipation means arranged on the hollow thermally insulating stand, thereby achieving effective anti-dust and intensive heat dissipation effects. Further, the electrically and thermally insulating rigid substrate makes the installation of the radiator convenient and effectively insulates the cold face (i.e. cooling face) and the hot face (i.e. heat dissipating face) of the semiconductor cooling plate, thus enhancing the heat dissipation efficiency. The radiator of the present disclosure has a simple structure, a good anti-dust effect, a noise free feature, and a stable and reliable heat dissipation performance and is easy to install.

A fixation component for fixing the semiconductor cooling plate 5 is arranged at an upper opening of the hollow thermally insulating stand 2, and an outer side wall of the semiconductor cooling plate 5 cooperates with an inner side wall at the upper opening of the hollow thermally insulating stand 2. In order to ensure the effective conduction of the heat, the outer side wall of the semiconductor cooling plate 5 is in an interference fit with the inner side wall of the hollow thermally insulating stand 2, thus effectively preventing dusts from entering to the hollow thermally insulating stand 2. At the same time, the fixation component functions to protect and fix the semiconductor cooling plate 5, or the semiconductor cooling plate 5 can be inserted directly into the upper opening of the hollow thermally insulating stand 2.

A clamping groove for snap-fitting with the fixation component is arranged on the outer side wall around the semiconductor cooling plate 5.

The fixation component includes a fixed member 8 and a movable member 9, the fixed member 8 is U-shaped and has a protrusion for snap-fitting with the clamping groove on its inner side wall, and the movable member 9 snap-fits with a clamping groove on a side of the semiconductor cooling plate 5 where a power line is arranged, and is fastened with the end face of the hollow thermally insulating stand 2. The movable member 9 can be fastened on the hollow thermally insulating stand 2 through a countersunk head tapping screw and high-temperature resistant super glue, thus the semiconductor cooling plate 5 can be thereby effectively and firmly fixed. In order to ensure good anti-dust and heat insulating effects and conduct heat effectively, the high-temperature resistant super glue is used to seal the gap between the fixation component and the thermally insulating stand, such that the cold face and the hot face of the semiconductor cooling plate 5 are insulated completely. At the same time, a tile on the hot face of the semiconductor cooling plate 5 projects from an upper plane of the fixed member 8, which is beneficial to the close engagement between the semiconductor cooling plate and the heat dissipation means.

The lower heat conductive connection base 3 includes a base and a stage arranged on the top of the base. A side wall of the stage is in an interference fit with the through hole and the inner side wall of the hollow thermally insulating stand 2. The stage extends through the through hole and a top surface of the stage abuts against the bottom surface of the semiconductor cooling plate 5. Further, the stage conducts effectively heat from the below heat source through the lower heat conductive connection base 3 and is insulated sufficiently with the hot face, thereby essentially enhancing the heat dissipation efficiency.

The semiconductor radiator further includes a compression component for compressing the upper heat conductive connection base 6 and the lower heat conductive connection base 3 and a supporting component for preventing the semiconductor cooling plate 5 from fracturing due to the compression.

The compression component includes a U-shaped bolt 10 and a pressing plate 11 cooperating with the U-shaped bolt, and an elastic pressing flake 12 is arranged on the bottom of the pressing plate 11. The elastic pressing flake can effectively adjust the pressing force among the various heat dissipation components, thereby effectively avoiding the fracture of the semiconductor cooling plate caused by the excessive pressing force.

The supporting component includes a number of pressure limiting screws 13 for positioning and supporting arranged between the electrically and thermally insulating rigid substrate 1 and the upper and lower heat conductive connection bases 6, 3, and nuts cooperating with threads at both ends of the pressure limiting screws for positioning and supporting 13, where the nuts include a first nut 14 for supporting and/or a second nut 15 for locking. The first nut 14 for supporting can effectively adjust the pressing force caused by the upper and lower heat conductive connection bases 6, 3 on the semiconductor cooling plate 5, thereby effectively avoiding the risk of the fracture of the semiconductor cooling plate 5 caused by the excessive pressing force. Further, with such a structure, the various components can be attached closely to form an integrated piece, thereby effectively ensuring the reliability of the connection between the components of the semiconductor radiator.

The heat dissipation means 7 is a heat sink provided with a ventilation hole and a ventilation groove at its bottom, so that the heat dissipation area of the heat sink itself and the air flow for heat dissipation are increased, and the heat dissipation performance of the heat sink is improved. The heat dissipation means may also be a fan-free radiator having a heat pipe, which can further promote the heat dissipation efficiency without causing noise.

The technical principle of the present invention has been described with reference to the embodiment. These descriptions are just to explain the principle of the present invention, rather than to limit the protection scope of the present invention in any ways. Other embodiments of the present invention conceived by the skilled in the art without pay any inventive labor fall into the protection scope of the present invention.

1. A semiconductor radiator, comprising an electrically and thermally insulating rigid substrate (1) containing a through hole, wherein a hollow thermally insulating stand (2) and a lower heat conductive connection base (3) are arranged at an upper end and a lower end of the through hole, respectively, a stage which extends through the through hole and cooperates with a cavity of the hollow thermally insulating stand (2) is arranged on the lower heat conductive connection base (3), a top surface of the stage is attached to a bottom surface of a semiconductor cooling plate (5) arranged on the top of the hollow thermally insulating stand (2), an upper heat conductive connection base (6) is attached to a top surface of the semiconductor cooling plate (5), and a number of heat dissipation means (7) are fastened on each of an upper surface of the upper heat conductive connection base (6) and a bottom surface of the lower heat conductive connection base (3).

2. The semiconductor radiator according to claim 1, wherein a fixation component for fixing the semiconductor cooling plate (5) is arranged at an upper opening of the hollow thermally insulating stand (2), and an outer side wall of the semiconductor cooling plate (5) cooperates with an inner side wall at the upper opening of the hollow thermally insulating stand (2).

3. The semiconductor radiator according to claim 2, wherein a clamping groove for snap-fitting with the fixation component is arranged on the outer side wall around the semiconductor cooling plate (5).

4. The semiconductor radiator according to claim 3, wherein the fixation component comprises a fixed member (8) and a movable member (9), the fixed member (8) is U-shaped and has a protrusion for snap-fitting with the clamping groove on an inner side wall of the fixed member (8), and the movable member (9) snap-fits with a clamping groove on a side of the semiconductor cooling plate (5) where a power line is arranged, and is fastened with the end face of the hollow thermally insulating stand (2).

5. The semiconductor radiator according to claim 1, wherein the lower heat conductive connection base (3) comprises a base and a stage arranged on the top of the base, and a side wall of the stage is in an interference fit with the through hole and the inner side wall of the hollow thermally insulating stand (2).

6. The semiconductor radiator according to claim 1, further comprising a compression component for compressing the upper heat conductive connection base (6) and the lower heat conductive connection base (3) and a supporting component for preventing the semiconductor cooling plate (5) from fracturing.

7. The semiconductor radiator according to claim 6, wherein the compression component comprises a U-shaped bolt (10) and a pressing plate (11) cooperating with the U-shaped bolt (10), and an elastic pressing flake (12) is arranged on the bottom of the pressing plate (11).

8. The semiconductor radiator according to claim 7, wherein the supporting component comprises a number of pressure limiting screws (13) for positioning and supporting arranged between the electrically and thermally insulating rigid substrate (1) and the upper and lower heat conductive connection base (6, 3), and nuts cooperating with threads at both ends of the pressure limiting screws (13) for positioning and supporting, wherein the nuts comprises a first nut (14) for supporting and/or a second nut (15) for locking.

9. The semiconductor radiator according to claim 1, wherein the heat dissipation means (7) is a heat sink provided with a ventilation hole and a ventilation groove at its bottom.
